(19) United States
(12) Patent Application Publication
(10) Pub. No.: US 2007/0262466 A1
(43) Pub. Date: Nov. 15, 2007

(54) Semiconductor device

(75) Inventor: Yasuki Fukui, Sakai-shi (JP)

Correspondence Address: NIXON & VANDERHYE, PC, 901 NORTH GLEBE ROAD, 11TH FLOOR, ARLINGTON, VA, 22203, US

(73) Assignee: Sharp Kabushiki Kaisha, Osaka (JP)

(21) Appl. No.: 11/783,517

(22) Filed: Apr. 10, 2007

(30) Foreign Application Priority Data
Apr. 18, 2006 (JP) 2006-115026

(51) Int. Cl. H01L 23/52; H01L 23/48; H01L 29/40

(52) U.S. Cl. 257/777

(57) ABSTRACT

A semiconductor device of the present invention includes a first semiconductor chip, a second semiconductor chip, and an adhesive layer, sandwiched between the first and second semiconductor chips, which adheres to the first semiconductor chip 2, the first and second semiconductor chips being laminated so that part of the second semiconductor chip protrudes outwards from an outer edge of the first semiconductor chip, the adhesive layer adhering to the first semiconductor chip so as to avoid an outer edge of the first semiconductor chip from which outer edge portion the part of the second semiconductor chip protrudes outwards. This makes it possible to provide a semiconductor device having a highly reliable (durable) laminated structure in which semiconductor chips are laminated.

This Nonprovisional application claims priority under 35 U.S.C. §119(a) on Patent Application No. 115026/2006 filed in Japan on Apr. 18, 2006, the entire contents of which are hereby incorporated by reference.

### FIELD OF THE INVENTION

The present invention relates to semiconductor devices. More specifically, the present invention relates to a semiconductor device including a large number of semiconductor chips in a single package.

### BACKGROUND OF THE INVENTION

Currently, a widely known method for manufacturing a semiconductor device whose size has been reduced and whose performance has been improved is a method for laminating a plurality of semiconductor chips in a single package.

Semiconductor devices each having a plurality of semiconductor chips laminated in a single package are used in various apparatuses such as a memory that is to be provided in a portable phone. The use of such a semiconductor device in a memory makes it possible to add value to the memory, and to increase the capacity of the memory.

Since semiconductor devices are used in a wide range, it is hoped that the size of a semiconductor chip is further reduced and that the performance of the semiconductor device is further improved. Techniques for meeting this request include (i) increasing the number of semiconductor chips to be laminated, (ii) thinning semiconductor chips, and (iii) thinning a packaged semiconductor device.

In cases where a plurality of semiconductor chips are laminated, each of the semiconductor chips needs to be bonded. Each of the semiconductor chips is bonded, for example, by a method for potting an adhesive.

In cases where the method for potting an adhesive is adopted, the amount of adhesive used has an influence on the size or reliability (durability) of a semiconductor device. If the amount of adhesive used is too large for the size of a semiconductor chip, the adhesive runs off the semiconductor chip. This makes it difficult to achieve high-density wiring.

Further, too small an amount of adhesive used leaves a gap between two semiconductor chips. For this reason, in cases where the gap cannot be filled by plastic-molding packaging, the semiconductor chips are caused to come off.

As a technique for solving this problem, a technique for forming a semiconductor device is disclosed in Japanese Unexamined Patent Application No. 204720/1999 (Tokukaihei 11-204720; published on Jul. 30, 1999). According to this technique, a semiconductor wafer to which an insulating adhesive layer has been bonded is cut into semiconductor chips of the same size.

In the following, a technique for thinning semiconductor chips is described as a technique for further reducing the size of a semiconductor device and further improving the performance of the semiconductor device.

Examples of the method for thinning semiconductor chips include (i) thinning a semiconductor wafer or (ii) miniaturizing an active element that is to be formed on the semiconductor wafer. A semiconductor wafer can be thinned by grinding the semiconductor wafer for a longer time after an element has been formed on the semiconductor wafer. Further, an insulating material called Low-k, which has a low dielectric constant, has drawn attention as a material for an insulating film for miniaturizing an active element that is to be formed on a semiconductor wafer, although the insulating material is so porous as to have a low mechanical strength.

Finally, thinning of a packaged semiconductor device causes laminated semiconductor chips to be placed at a short distance from each other. This causes an unintentional contact between a semiconductor chip and a wire. A technique for securely insulating laminated semiconductor chips from each other is disclosed in Japanese Unexamined Patent Application No. 222913/2002 (Tokukai 2002-222913; published on Aug. 9, 2002).

In case of a semiconductor package in which laminated semiconductor chips are electrically connected by wire bonding, in which the thickness of the semiconductor chips is great, and in which the number of semiconductor chips laminated is small, there has been no special problem with stress to be caused in the semiconductor package.

However, an increase in the number of semiconductor chips and thinning of the semiconductor chips lead to an increase in internal stress of a packaged semiconductor device. The increase in internal stress of the package causes damage to the semiconductor chips, thereby possibly hindering electrical functions of the semiconductor device.

In addition to this, especially when a material having a low mechanical strength is used for a structure that is to be provided in a semiconductor chip, the semiconductor chip becomes breakable.

However, neither Tokukaihei 11-204720 nor Tokukai 2002-222913 discloses a method for solving problems such as (i) an increase in stress and (ii) damage caused to a semiconductor chip due to the increase in stress.

An increase in internal stress of a package causes an increase in frequency of damage of an outer edge portion of a semiconductor chip. This is considered to be due to a step of cutting a semiconductor wafer into semiconductor chips. A general example of the method for cutting a semiconductor wafer into semiconductor chips is a step of dicing (dividing) a semiconductor wafer into semiconductor chips by using a diamond blade.

In cases where a Si semiconductor wafer is divided into Si semiconductor chips by dicing, each of the Si semiconductor chips has a cut surface serving as an outer edge portion of the Si semiconductor chip, and the outer edge portion has minute physical defects such as (i) formation of a crushed layer, (ii) chippage, and (iii) minute exfoliation of an element. If such packaging is performed that stress is applied to an outer edge portion of a semiconductor chip which outer edge portion has a minute physical defect, damage of the semiconductor chip progresses from the minute physical defect. This may cause a fatal defect (a failure in the electrical function of a semiconductor device).

In addition to this, when a semiconductor device is exposed to (i) a high temperature (not less than 240° C.) reached when the semiconductor device is mounted by soldering and to (ii) a repetitive temperature cycle load, there is an increase in stress. This causes damage to a semiconductor chip of the semiconductor device. In cases where the damage of the semiconductor chip progresses, a fragile layer in that surface of the semiconductor chip which is provided with an active element is damaged. This may hinder electrical functions of an integrated circuit.

It is assumed that a state in which an outer edge portion of a semiconductor chip is easily subjected to a load and damaged is a case where an adhesive layer for bonding a later laminated semiconductor chip is in contact with an outer edge portion of an earlier laminated semiconductor chip. It is assumed that specific examples of such a state are as follows:

(1) a state in which at least part of a later laminated semiconductor chip protrudes outwards from an outer edge of an earlier laminated semiconductor chip and in which an adhesive layer is in contact with an outer edge portion of the earlier laminated semiconductor chip; and

(2) a state in which at least part of a later laminated semiconductor chip overlaps with at least part of an earlier laminated semiconductor chip when the two semiconductor chips are seen directly from above and in which an adhesive layer is in contact with an outer edge portion of the earlier laminated semiconductor chip.

### SUMMARY OF THE INVENTION

The present invention has been made in view of the foregoing problems, and it is an object of the present invention to provide, by reducing stress loading that is to be applied to an outer edge portion of a semiconductor chip, a semiconductor device having a highly reliable (durable) laminated structure in which semiconductor chips are laminated.

In order to solve the foregoing problems, a semiconductor device of the present invention includes: a first semiconductor chip having a main surface provided with electrode terminals and a back surface that is on an opposite side of the main surface; a second semiconductor chip having a main surface provided with electrode terminals and a back surface that is on an opposite side of the main surface; an adhesive layer, sandwiched between the first and second semiconductor chips, which adheres to the first semiconductor chip, the first and second semiconductor chips being laminated so that part of the second semiconductor chip protrudes outwards from an outer edge of the first semiconductor chip, in an outer edge portion of the first semiconductor chip from whose outer edge the part of the second semiconductor chip protrudes outwards, the adhesive layer adhering to the first semiconductor chip so as to be short of the outer edge of the first semiconductor chip.

In the foregoing arrangement, a structure in which the plurality of semiconductor chips are laminated within a single package so that the part of the second semiconductor chip protrudes outwards from the outer edge of the first semiconductor chip is referred to as “protruding laminated structure”.

In the arrangement of the present invention, the part of the second semiconductor chip protrudes outwards from the outer edge of the first semiconductor chip. When an adhesive layer for laminating the second semiconductor chip comes into contact with an outer edge portion of the first semiconductor chip from whose outer edge the part of the second semiconductor chip protrudes outwards, a load is easily applied especially to the outer edge portion of the first semiconductor chip, so that stress is easily concentrated on the outer edge portion of the first semiconductor chip.

In light of this, according to the present invention, at least in the outer edge portion, the adhesive layer adheres to the first semiconductor chip so as to be short of the outer edge of the first semiconductor chip. This makes it possible to reduce the load applied to the outer edge portion.

Therefore, since the load applied to the outer edge portion having a large number of minute physical defects is reduced, damage of the first semiconductor chip can be prevented from progressing from such a minute physical defect.

As a result, the reliability (durability) of a semiconductor device whose size has been reduced and whose performance has been improved by having a protruding laminated structure can be improved.

Additional objects, features, and strengths of the present invention will be made clear by the description below. Further, the advantages of the present invention will be evident from the following explanation in reference to the drawings.

### BRIEF DESCRIPTION OF THE DRAWINGS

FIG. 1(a) is a perspective view of a semiconductor device in which a later laminated semiconductor chip protrudes outwards from an earlier laminated semiconductor chip laminated.

FIG. 1(b) is a cross-sectional view taken along the arrow A1-A2 of FIG. 1(a).

FIG. 1(c) is a perspective view explaining an adhesive layer of a conventional semiconductor device.

FIG. 2(a) is a perspective view showing a modified example of the semiconductor device of FIG. 1.

FIG. 2(b) is a cross-sectional view taken along the arrow B1-B2 of FIG. 2(a).

FIG. 2(c) is a perspective view explaining an adhesive layer of a conventional semiconductor device.

FIG. 3 is a perspective view showing steps of manufacturing a semiconductor device shown in FIGS. 1 and 2.

FIG. 4(a) is a perspective view of a semiconductor device in which chips of the same size are laminated.

FIG. 4(b) is a cross-sectional view taken along the arrow C1-C2 of FIG. 4(a).

FIG. 4(c) is a perspective view explaining an adhesive layer of a conventional semiconductor device.

FIG. 5(a) is a perspective view of a semiconductor device in which chips of the same size are laminated and in which an adhesive layer has a two-layer structure.

FIG. 5(b) is a cross-sectional view taken along the arrow D1-D2 of FIG. 5(a).

FIG. 5(c) is a perspective view explaining an adhesive layer of a conventional semiconductor device as opposed to a semiconductor device shown in FIGS. 5 and 6.

FIG. 6(a) is a perspective view showing a modified example of the semiconductor device of FIG. 5.

FIG. 6(b) is a cross-sectional view taken along the arrow E1-E2 of FIG. 6(a).

FIG. 7(a) is a perspective view of a semiconductor device in which chips of the same size are laminated and in which electrical connections are made using metal posts.

FIG. 7(b) is a cross-sectional view taken along the arrow F1-F2 of FIG. 7(a).

FIG. 7(c) is a perspective view explaining an adhesive layer of a conventional semiconductor device.

FIG. 8 is a perspective view showing steps of manufacturing a semiconductor device shown in FIGS. 4 through 7.

### DESCRIPTION OF THE EMBODIMENTS

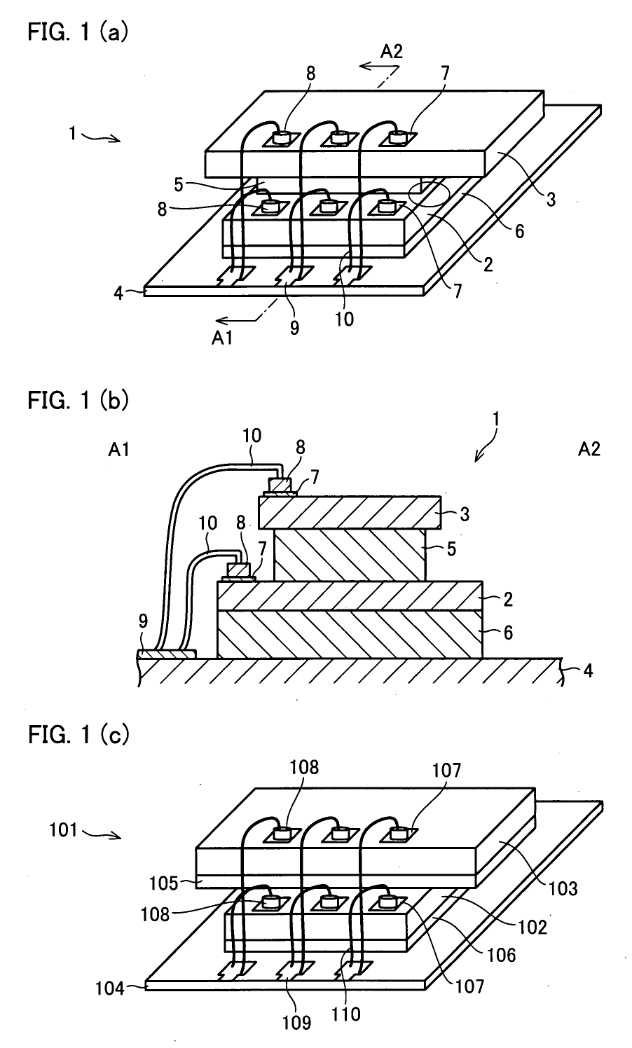

An embodiment of the present invention will be described below with reference to FIGS. 1 through 3.

In the description given below, the term “main surface of a semiconductor chip” refers to that surface of the semiconductor chip on which a structure having an electrical function (i.e., a structure such as an electrode terminal or an element) has been provided.

Further, the term “back surface of the semiconductor chip” is a surface that is opposite the main surface of the semiconductor chip, and refers to a surface that has been ground so that the semiconductor chip is thinned.

Furthermore, in cases where the semiconductor chip has a cuboidal shape, the term “outer edge of the semiconductor chip” refers to that part of the semiconductor chip which is on each of the sides of the rectangular main surface or rectangular back surface of the semiconductor chip. Alternatively, in cases where the semiconductor chip has a cylindrical shape, the term “outer edge of the semiconductor chip” refers to that part of the semiconductor chip which is around the circular main surface or circular back surface of the semiconductor chip. Moreover, the “outer edge portion of the semiconductor chip” refers to the outer edge of the semiconductor chip and to that part of the semiconductor chip which is near the outer edge.

Further, the same members or components in Embodiments 1 to 3 are given the same reference numerals, respectively. The same members or components in Embodiments 1 to 3 also have the same names and the same functions, respectively. Therefore, a detailed description thereof is not repeated. A semiconductor device of the present invention is not limited to the description of the embodiments below, but may be altered by a person skilled in the art within the scope of the claims.

### Embodiment 1

Referring to FIGS. 1(a) and 1(b), the present embodiment explains a semiconductor device structured such that a substrate and two semiconductor chips are laminated and that part of the semiconductor chip laminated above protrudes outwards from an outer edge of the semiconductor chip laminated below.

A semiconductor device 1 of the present embodiment includes an insulating substrate 4, a adhesive layer 6 (substrate adhesion layer) adhering to that surface of the substrate 4 which is provided with a wiring pattern 9, a semiconductor chip 2 (first semiconductor chip) whose back surface adheres to the adhesive layer 6, an adhesive layer 5 (adhesive layer recited in the claims) adhering to a main surface of the semiconductor chip 2, and a semiconductor chip 3 (second semiconductor chip) whose back surface adheres to the adhesive layer 5.

Note that the semiconductor chips 2 and 3 are laminated so that at least part of the semiconductor chip 3 protrudes outwards from an outer edge of the semiconductor chip 2. Hereinafter, a structure in which a plurality of semiconductor chips are laminated in a single package is referred to as “protruding laminated structure”.

In the arrangement shown in FIG. 1(a), each of the semiconductor chip 2 and the semiconductor chip 3 has a flat cuboidal shape, and therefore has a rectangular main surface and a rectangular back surface. Therefore, in the protruding laminated structure, the semiconductor chips 2 and 3 are laminated so that the longer sides of the main and back surfaces of the semiconductor chip 2 intersect with the longer sides of the main and back surfaces of the semiconductor chip 3.

As a result, end portions (i.e., outer edges) of the longer sides of the main and back surfaces of the semiconductor chip 3 protrude outwards from the longer sides (i.e., outer edges) of the main and back surfaces of the semiconductor chip 2. Furthermore, in the vicinity of a shorter side of the main surface of the semiconductor chip 2, there exists a region in which electrode terminals 7 and/or other members can be provided.

Thus, in the vicinity of the shorter side of the main surface of the semiconductor chip 2, a plurality of electrode terminals 7 are provided. Furthermore, in the vicinity of that longer side of the main surface of the semiconductor chip 3 which corresponds to the shorter side of the main surface of the semiconductor chip 2, a plurality of electrode terminals 7 are provided. Each of the electrode terminals 7 is provided with a bump 8 (element constituting an electrical conductor).

Furthermore, the bump 8 is connected to a wire 10 (element constituting an electrical conductor), and the wire 10 is connected to the wiring pattern 9.

Here, attention should be focused on the fact that: in an outer edge portion of the semiconductor chip 2 from whose outer edge the semiconductor chip 3 protrudes outwards, the adhesive layer 5 adheres to the semiconductor chip 2 so as to be short of an outer edge of semiconductor chip 2. That is, the adhesive layer 5 is not in contact with the outer edge portion of the semiconductor chip 2 (see FIGS. 1(a) and 1(b)).

Thus, a semiconductor device 1 according to the present invention at least includes: a first semiconductor chip 2 having a main surface provided with electrode terminals 7 and a back surface that is opposite the main surface; a second semiconductor chip 3 having a main surface provided with electrode terminals 7 and a back surface that is opposite the main surface; and an adhesive layer 5, sandwiched between the first an second semiconductor chips 2 and 3, which adheres to the semiconductor chip 2, the first and second semiconductor chips 2 and 3 being laminated so that part of the second semiconductor chip 3 protrudes outwards from an outer edge of the first semiconductor chip 2, in an outer edge portion of the first semiconductor chip 2 from whose outer edge the part of the second semiconductor chip 3 protrudes outwards, the adhesive layer 5 adhering to the first semiconductor chip 2 so as to be short of the outer edge of the first semiconductor chip 2.

With this, even in cases where a plurality of semiconductor chips are laminated, it is possible to prevent stress from being concentrated on the outer edge portion of the semiconductor chip 2, so that the semiconductor chip 2 becomes unlikely to be physically damaged. As a result, the reliability (durability) of the semiconductor device 1 can be enhanced.

Furthermore, in an outer edge portion of the semiconductor chip 3 which outer edge portion overlaps with the semiconductor chip 2, the adhesive layer 5 adheres to the semiconductor chip 3 so as to be short of an outer edge portion of the semiconductor chip 3. That is, the adhesive layer 5 is not in contact with the outer edge portion of the semiconductor chip 3 (see FIGS. 1(a) and 1(b).

Thus, in addition to the foregoing arrangement, the semiconductor device 1 according to the present invention is further arranged such that: in the outer edge portion of the first semiconductor chip 2 from which outer edge portion the part of the second semiconductor chip 3 protrudes outwards, the adhesive layer 5 adheres to the first semiconductor chip 3 so as to be short of the outer edge of the second semiconductor chip 3.

With this, even in cases where a plurality of semiconductor chips are laminated, it is possible to prevent stress from being concentrated on the outer edge portion of the semiconductor chip 3, as with the semiconductor chip 2, so that the semiconductor chip 3 becomes unlikely to be physically damaged. As a result, the reliability (durability) of the semiconductor device 1 can be further enhanced.

The semiconductor device 1 of the present embodiment is arranged such that the first and second semiconductor chips 2 and 3 are bonded to each other solely by the adhesive layer 5. However, the first and second semiconductor chips 2 and 3 do not need to be bonded to each other solely by the adhesive layer 5, but may be bonded to each other by two or more adhesive layers.

Use of two or more adhesive layers makes it possible, for example, to securely insulate the first and second semiconductor chips 2 and 3 from each other. By appropriately referring to Reference Examples 2 and 3 described later, it is possible to adopt an arrangement according to which the semiconductor device 1 of the present invention uses two or more adhesive layers.

On the other hand, a conventional semiconductor device 101 shown in FIG. 1(c) includes an insulating substrate 104, an adhesive layer 106 adhering to that surface of the substrate 104 which is provided with a wiring pattern 109, a semiconductor chip 102 whose back surface adheres to the adhesive layer 106, an adhesive layer 105 adhering to a main surface of the semiconductor chip 102, and a semiconductor chip 103 whose back surface adheres to the adhesive layer 105.

Further, each of the semiconductor chips 102 and 103 has a main surface provided with a plurality of electrode terminals 107, and each of the electrode terminals 107 has a bump 108 connected thereto. Furthermore, the bump 108 is connected to a wire 110, and the wire 110 is connected to the wiring pattern 109 formed on the substrate 104.

The conventional semiconductor device 101 differs from the semiconductor device 1 of the present embodiment in that: in an outer edge portion of the first semiconductor chip 102 from whose outer edge an outer edge of the second semiconductor chip 103 protrudes outwards, the adhesive layer 105 is in contact with both the outer edge portion of the semiconductor chip 102 and an outer edge portion of the semiconductor chip 103.

As described above, a semiconductor chip is damaged rapidly due to a contact between (i) an outer edge portion of the semiconductor chip which outer edge portion has a large number of minute physical defects and (ii) an adhesive layer; therefore, the electrical function of the semiconductor chip is easily impaired. For this reason, the semiconductor device 101 is inferior to the semiconductor device 1 in terms of reliability (durability).

The above description explains the members used in the semiconductor device 1 of the present embodiment and the structure of the semiconductor device 1. The following description fully explains members and structures that can be suitably adopted in the semiconductor device of the present invention.

A substrate 4 that can be used in the semiconductor device 1 of the present invention is not particularly limited as long as the substrate 4 has an insulating surface provided with a wiring pattern made of a conductive material. That is, the substrate 4 may be entirely made of an insulating material, or may be a mostly conductive substrate that has an insulating surface.

Further, the substrate 4 of the semiconductor device of the present invention can be produced from a conventional well-known material, and can be made by a conventional well-known method. Therefore, it is not necessary to produce a substrate, and it is only necessary to prepare a substrate that can be suitably used in the semiconductor device of the present invention.

Examples of a material that can be used for a wiring pattern 9 to be formed on the substrate 4 include Cu, Al, Au, Ni, and the like. Among these materials, Cu is preferable because it can be obtained at low cost. Further, examples of a method for forming a wiring pattern on a substrate include an evaporation method, a plating method, and the like.

Each of the adhesive layers 5 and 6 used in the semiconductor device 1 of the present invention is not particularly limited as long as (i) it is a uniform layer made of an insulating adhesive and (ii) it can be prevented from making contact with an outer edge portion of a semiconductor chip when used for bonding of the semiconductor chip.

That is, an adhesive that can be adopted may take any form such as a liquid or a solid, and only needs to insulate a substrate from a semiconductor chip bonded thereto, or to insulate semiconductor chips from each other. For this reason, conventional well-known adhesives can be adopted, and bonding can be carried out using a conventional well-known method.

Among the adhesives that can be suitably used in the aforementioned semiconductor device of the present invention, a sheet-like adhesive which has a uniform thickness and which can be easily processed into a desired shape is more preferable. The reason for this is that such an adhesive can be prevented from making contact with an outer edge portion of a semiconductor chip.

Semiconductor chips 2 and 3 that can be used in the semiconductor device of the present invention are not particularly limited, but can be preferably produced from a conventional well-known material by a conventional well-known method. Further, the semiconductor device of the present embodiment only needs to be structured such that part of the semiconductor chip 3 protrudes from an outer edge portion of the semiconductor chip 2. Therefore, the semiconductor chips 2 and 3 may be equal or unequal in size.

Examples of a material for electrode terminals (7) to be formed on the semiconductor chips that can be used in the semiconductor device of the present invention include a commonly-used material such as Al or an Al alloy.

In the semiconductor device of the present invention, the plurality of semiconductor chips and the wiring pattern formed on the substrate can be electrically connected by a wire bonding method. However, the present invention is not limited to this. In the semiconductor device of the present invention, the substrate and the semiconductor chips can be electrically connected by a conventional well-known method.

As a conductive material to be used for making a connection by use of the wire bonding method, a conventional well-known material can be used. For example, the bump 8 can be made of, but is not limited to, solder, Au, Cu, or the like, and the wire 10 can be made of, but is not limited to, Au, Al, or the like.

### Embodiment 2

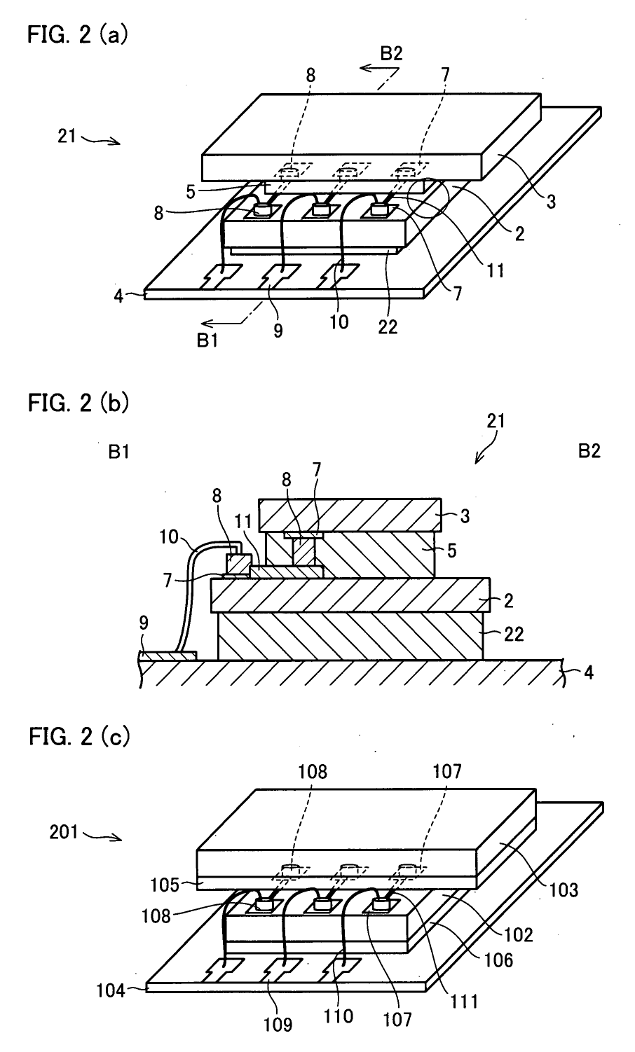

The present embodiment explains a semiconductor device 21 with reference to FIGS. 2(a) and 2(b). The semiconductor device 21 is a modified example of the semiconductor device 1 shown in Embodiment 1.

As with the semiconductor device 1, the semiconductor device 21 has a protruding laminated structure. However, in the semiconductor device 21, a main surface of a semiconductor chip 2 and a main surface of a semiconductor chip 3 are bonded to each other by an adhesive layer 5 so as to face each other. Further, a back surface of the semiconductor chip 2 is bonded to a substrate 4 by an adhesive layer 22. For this reason, the semiconductor chip 2 or 3 and a wiring pattern 9 formed on the substrate 4 are electrically connected to each other according to an arrangement described below.

The wiring pattern 9 formed on the substrate 4 and a first bump 8 provided on an electrode terminal 7 of the semiconductor chip 2 are connected to each other by a wire 10. Further, the first bump 8 and a second bump 8 that is provided on an electrode terminal 7 of the semiconductor chip 3 are connected to each other by a rewiring pattern 11 (element constituting an electrical conductor).

The electrode terminal of the semiconductor chip 3, the second bump 8, and the rewiring pattern 11 are wholly or partially covered with the adhesive layer 5.

Here, as with the semiconductor device 1 of Embodiment 1, the semiconductor device 21 is arranged such that: in an outer edge portion of the semiconductor chip 2 from whose outer edge the semiconductor chip 3 protrudes outwards, the adhesive layer 5 adheres to the semiconductor chip 2 so as to be short of an outer edge of the semiconductor chip 2. That is, the adhesive layer 5 is not in contact with an outer edge portion of the semiconductor chip 2.

Further, in an outer edge portion of the semiconductor chip 3 which outer edge portion overlaps with the semiconductor chip 2, the adhesive layer 5 adheres to the semiconductor chip 3 so as to be short of an outer edge of the semiconductor chip 3. That is, the adhesive layer 5 is not in contact with an outer edge portion of the semiconductor chip 3 (see FIGS. 2(a) and 2(b)).

With these arrangements, even in cases where a plurality of semiconductor chips are laminated, it is possible to prevent stress from being concentrated on an outer edge portion of the main surface of the semiconductor chip 2 and an outer edge portion of the main surface of the semiconductor chip 3, so that the semiconductor chip 2 becomes unlikely to be physically damaged. As a result, the reliability (durability) of the semiconductor device 1 can be enhanced.

Moreover, according to the present invention, the semiconductor device 21 differs significantly from the semiconductor device 1 in that the adhesive layer 22 for bonding the semiconductor chip 2 to the substrate 4 differs in shape from the adhesive layer 6.

The adhesive layer 22 is formed so as to have an adhesive surface having an area smaller than that of an adhesive surface of the adhesive layer 6 of Embodiment 1. Moreover, the adhesive layer 22 adheres to a back surface of the semiconductor chip 2 so as to be short of an outer edge portion of the back surface.

With this, it is possible to prevent stress from being concentrated on the outer edge portion of the back surface of the semiconductor chip 2, so that the semiconductor chip 2 becomes unlikely to be physically damaged. Therefore, the reliability (durability) of the semiconductor device 21 can be further enhanced.

On the other hand, in a conventional semiconductor device 201 shown in FIG. 2(c), an adhesive layer 105 is in contact with both an outer edge portion of a main surface of a semiconductor chip 102 and an outer edge portion of a main surface of a semiconductor chip 103. Further, an adhesive layer 106 is in contact with an outer edge portion of a back surface of the semiconductor chip 102.

With this, physical damage of the semiconductor chips 102 and 103 is easily accelerated. Therefore, the semiconductor device 201 is inferior to the semiconductor device 21 in terms of reliability (durability).

The semiconductor device 21 of the present embodiment is arranged such that the first and second semiconductor chips 2 and 3 are bonded to each other solely by the adhesive layer 5. However, the first and second semiconductor chips 2 and 3 do not need to be bonded to each other solely by the adhesive layer 5, but may be bonded to each other by two or more adhesive layers.

By appropriately referring to Reference Examples 2 and 3 described later, it is possible to adopt an arrangement according to which the semiconductor device 21 of the present invention uses two or more adhesive layers.

### Embodiment 3

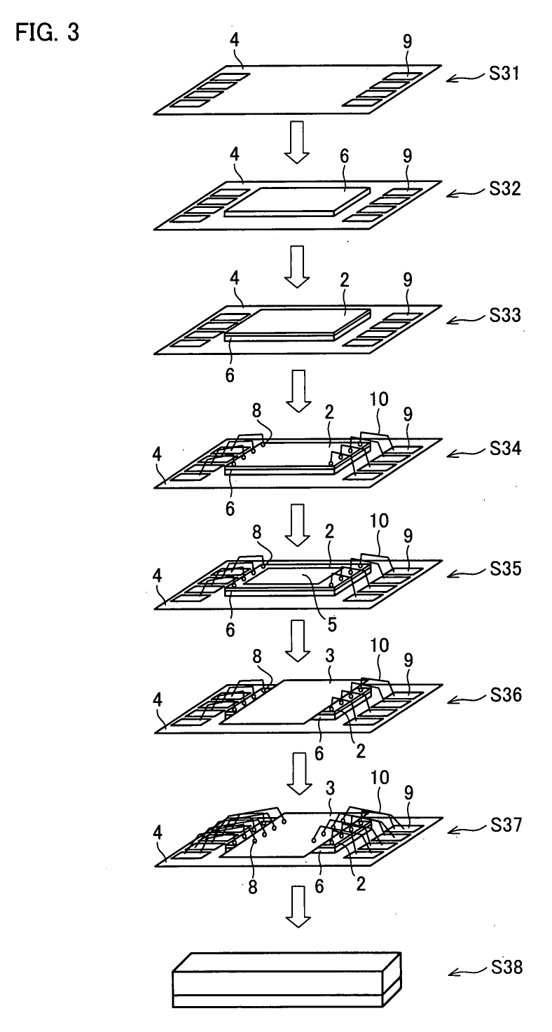

Referring to FIG. 3, the present embodiment explains an example of a method for manufacturing a semiconductor device, described in Embodiment 1, which is structured such that a substrate and two semiconductor chips are laminated and that part of the semiconductor chip laminated above protrudes outwards from an outer edge portion of the semiconductor chip laminated below.

In a first step, an insulating substrate 4 provided with a wiring patter 9 is prepared (Step 31; hereinafter referred to as “S31”).

In a second step, a first adhesive layer 6 is formed on that surface of the substrate 4 which is provided with the wiring pattern 9 (S32).

Here, the adhesive layer 6 is formed by using a sheet-like adhesive which has a uniform thickness and which makes it easy to determine a position of adhesion. However, the adhesive layer 6 only needs to be made of an adhesive that can be prevented from adhering to an outer edge portion of a semiconductor chip.

In a third step, a first semiconductor chip 2 is disposed (S33).

Here, the semiconductor chip 2 has a main surface provided with electrode terminals 7, has a back surface ground in advance, and is obtained by dicing.

Further, in FIG. 3, an outer edge portion of the back surface of the first semiconductor chip 2 is in contact with the adhesive layer 6. However, in S32, the adhesive layer 6 may have a smaller area so as not to make contact with the outer edge portion of the semiconductor chip 2.

In a fourth step, each of the electrode terminals 7 formed on the first semiconductor chip 2 and the wiring pattern 9 formed on the substrate 4 are electrically connected to each other by wire bonding (S34).

Here, a bump 8 that has been formed on each of the electrode terminals 7 may be connected to the wiring patter 9 by a wire 10. Alternatively, a bump 8 that has been formed in an end portion of a wire 10 may be connected to the electrode terminal 7.

In a fifth step, a second adhesive layer 5 is formed on the main surface of the first semiconductor chip 2 (S35).

Here, the size of the second adhesive layer 5 and the position of adhesion of the second adhesive layer 5 need to be accurately determined so that the second adhesive layer 5 does not make contact with an outer edge portion of the main surface of the first semiconductor chip 2.

In a sixth step, a second semiconductor chip 3 is laminated on the second adhesive layer 5 formed on the main surface of the first semiconductor chip 2 (S36).

On this occasion, the second semiconductor chip 3 is laminated so as to protrude from the outer edge of the first semiconductor chip 2.

Further, in FIG. 3, the first semiconductor chip 2 and the second semiconductor chip 3 are orthogonal to each other. However, it is only necessary that part of the second semiconductor chip 3 protrudes from the outer edge of the first semiconductor chip 2.

Furthermore, the second semiconductor chip has a main surface provided with electrode terminals, has a back surface ground in advance, and is obtained by dicing.

In a seventh step, each of the electrode terminals 7 formed on the second semiconductor chip 3 and the wiring pattern 9 formed on the substrate 4 are electrically connected to each other by wire bonding (S37).

Here, the electrical connection is made by wire boding in the same manner as in S34.

In an eighth step, the laminated structure which has been formed on the substrate 4 and in which the two semiconductor chips 2 and 3 are laminated is packaged by plastic molding (S38).

Here, examples of a method for packaging the laminated structure by plastic molding include, but is not limited to, a transfer molding method, a potting method, and the like. As the method for packaging the laminated structure by plastic molding, a conventional well-known method can be suitably used.

The present embodiment takes plastic molding as an example. However, a highly moisture-resistant airtight sealant made of an inorganic substance such as ceramic, glass, or metal may be used.

Note that the semiconductor device described in Embodiment 2 can be manufactured by changing the aforementioned steps in the following manner.

(1) In S33, a first semiconductor chip 2 having a main surface provided with a rewiring pattern 11 is bonded.

(2) After S35, the adhesive layer 5 is provided with an opening through which the rewiring pattern 11 and a bump 8 that is to be connected to the rewiring pattern 11 can be connected to each other.

(3) In S36, a second semiconductor chip 3 having a main surface on which an electrode terminal 7 provided with the bump 8 has been formed is laminated.

(4) S38 is carried out without carrying out S37.

The present embodiment describes an example of the method for manufacturing a semiconductor device according to the present invention. However, a person skilled in the art can easily imagine that a conventional well-known semiconductor device manufacturing step can be used for manufacturing a semiconductor device of the present invention and that the aforementioned steps can be appropriately altered as needed.

### REFERENCE EXAMPLE 1

As with Embodiments 1 to 3, the following shows various examples. In each of the examples, a structure in which an adhesive layer sandwiched between two semiconductor chips makes no contact with either of the two semiconductor chips by the outer edge portion is applied in cases where one of the two semiconductor chips has at least a side that overlaps with at least a side of the other one of the two semiconductor chips.

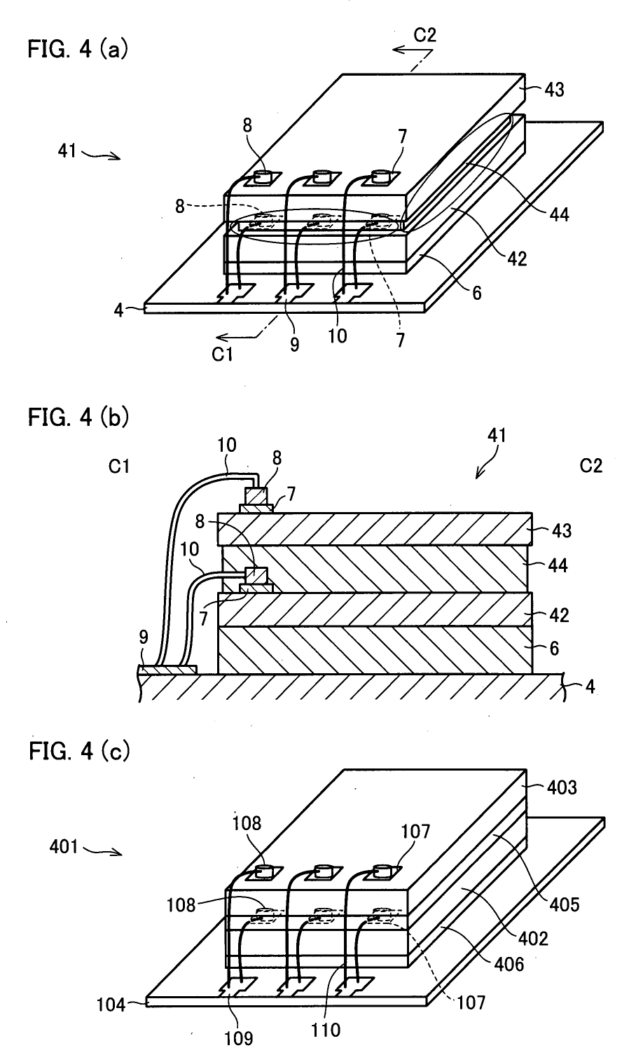

Referring to FIGS. 4(a) and 4(b), the present reference example explains a case where a semiconductor device has a structure in which two semiconductor chips of the same size are laminated above a substrate, and where the two semiconductor chips have the same shape so as to coincide with each other as the laminated structure in which the two semiconductor chips are laminated is observed directly from above.

A semiconductor device 41 of the present reference example includes an insulating substrate 4, an adhesive layer 44 adhering to that surface of the substrate 4 which is provided with a wiring pattern 9, a semiconductor chip 42 whose back surface adheres to the adhesive layer 44, an adhesive layer 6 adhering to a main surface of the semiconductor chip 42, and a semiconductor chip 43 whose back surface adheres to the adhesive layer 6.

In the arrangement shown in FIG. 4(a), each of the semiconductor chip 42 and the semiconductor chip 43 has a flat cuboidal shape, and therefore has a rectangular main surface and a rectangular back surface. Further, the respective main and back surfaces of the semiconductor chips 42 and 43 have the same size. Therefore, in cases where a structure in which the semiconductor chips 42 and 43 are laminated is seen directly from above, all the sides of one of the two semiconductor chips appear to coincide with all the sides of the other one of the two semiconductor chips, respectively.

Further, in the vicinity of a shorter side of the main surface of the semiconductor chip 42, a plurality of electrode terminals 7 are provided. Similarly, in the vicinity of a shorter side of the main surface of the semiconductor chip 43, a plurality of electrode terminals 7 are provided. Each of the electrode terminals 7 has a bump 8 connected thereto.

Furthermore, the bump 8 is connected to a wire 10, and the wire 10 is connected to the wiring pattern 9.

The electrode terminal 7 provided on the main surface of the semiconductor chip 42, the bump 8 connected to the electrode terminal 7, and part of the wire 10 connected to the bump 8 are covered with an adhesive layer 44.

This makes it possible to prevent each wire 10 from making contact with the semiconductor chip 43, so that the semiconductor chips 42 and 43 are securely insulated from each other.

Here, attention should be focused on the fact that: in an outer edge portion of the semiconductor chip 42, the adhesive layer 44 adheres to the semiconductor chip 42 so as to be short of an outer edge of the semiconductor chip 42. That is, the adhesive layer 44 is not in contact with the outer edge portion of the semiconductor chip 42 (see FIGS. 4(a) and 4(b)).

Thus, a semiconductor device 41 of the present reference example at least includes: a first semiconductor chip 42 having a main surface provided with electrode terminals 7 and a back surface that is opposite the main surface; a second semiconductor chip 43 having a main surface provided with electrode terminals 7 and a back surface that is opposite the main surface; and an adhesive layer 44, sandwiched between the semiconductor chips 42 and 43, which adheres to the semiconductor chips 42 and 43, the first and second semiconductor chips 42 and 43 being laminated so that at least part of an outer edge of the second semiconductor chip 43 overlaps with at least part of an outer edge of the first semiconductor chip 42, at least in an outer edge portion of the first semiconductor chip 42 which outer edge portion overlaps with the outer edge of the second semiconductor chip 43, the adhesive layer 44 adhering to the first semiconductor chip 42 so as to be short of the outer edge of the first semiconductor chip 42.

Here, the adhesive layer 44 is not in contact with the outer edge portion of the first semiconductor chip 42 (see FIGS. 4(a) and 4(b)).

With this, even in cases where a plurality of semiconductor chips are laminated, it is possible to prevent stress from being concentrated on the outer edge portion of the semiconductor chip 42, so that the semiconductor chip 42 becomes unlikely to be physically damaged. As a result, the reliability (durability) of the semiconductor device 41 can be enhanced.

Furthermore, in an outer edge portion of the semiconductor chip 43, the adhesive layer 44 adheres to the semiconductor chip 43 so as to be short of the outer edge of the semiconductor chip 43. That is, the adhesive layer 44 is not in contact with the outer edge portion of the semiconductor chip 43 (see FIGS. 4(a) and 4(b)).

Thus, in addition to the foregoing arrangement, the semiconductor device 41 of the present reference example is further arranged such that: at least in an outer edge portion of the first semiconductor chip 42 from whose outer edge the outer edge of the second semiconductor chip 43 protrudes outwards, the adhesive layer 44 adheres to the second semiconductor chip 43 so as to be short of the outer edge of the second semiconductor chip 43.

With this, even in cases where a plurality of semiconductor chips are laminated, it is possible to prevent stress from being concentrated on the outer edge portion of the semiconductor chip 43, as with the semiconductor chip 42, so that the semiconductor chip 43 becomes unlikely to be physically damaged. As a result, the reliability (durability) of the semiconductor device 41 can be further enhanced.

With this, the semiconductor chip 43 similarly becomes unlikely to be physically damaged due to stress concentration, so that the reliability (durability) of the semiconductor device 41 can be further enhanced.

On the other hand, a conventional semiconductor device 401 includes an insulating substrate 104, an adhesive layer 406 adhering to that surface of the substrate 104 which is provided with a wiring pattern 109, a semiconductor chip 402 whose back surface adheres to the adhesive layer 406, an adhesive layer 405 adhering to a main surface of the semiconductor chip 402, and a semiconductor chip 403 whose back surface adheres to the adhesive layer 405.

Further, on each of the main surfaces of the. semiconductor chips 402 and 403, a plurality of electrode terminals 107 are provided. Each of the electrode terminals 107 has a bump 108 connected thereto. Furthermore, the bump 108 is connected to a wire 110, and the wire 110 is connected to the wiring pattern 109 formed on the substrate 104.

As shown in FIG. 4(c), the conventional semiconductor chip 401 differs from the semiconductor device 41 of the present reference example in that the adhesive layer 405 is in contact with both an outer edge portion of the semiconductor chip 402 and an outer edge portion of the semiconductor chip 403.

As described above, a semiconductor chip is damaged rapidly due to a contact between (i) an outer edge portion of the semiconductor chip which outer edge portion has a large number of minute physical defects and (ii) an adhesive layer; therefore, the electrical function of the semiconductor chip is easily impaired. For this reason, the semiconductor device 401 is inferior to the semiconductor device 41 in terms of reliability (durability).

The above paragraphs explain the members used in the semiconductor device 41 of the present embodiment and the structure of the semiconductor device 41. The following description fully explains a structure of a semiconductor chip that can be suitably used in the semiconductor device of the present invention.

According to the case explained in the present reference example, when the laminated structure in which the two semiconductor chips having the same size are laminated is observed directly from above, the semiconductor device has the structure in which the two conductor chips coincide with each other. However, the semiconductor device of the present reference example only needs to have a structure in which the two semiconductor chips at least partially overlap with each other, and the two semiconductor chips do not need to have the same size.

### REFERENCE EXAMPLE 2

A semiconductor device 51 of the present reference example is a modified example of the semiconductor device 41 shown in Reference Example 1, and is structured such that an adhesive layer for boding two semiconductor chips of the same size to each other is constituted by two layers of different sizes.

As described above, in the semiconductor device 51, the semiconductor chips 42 and 43 are bonded to each other by two layers, namely an adhesive layer 52 and an adhesive layer 53.

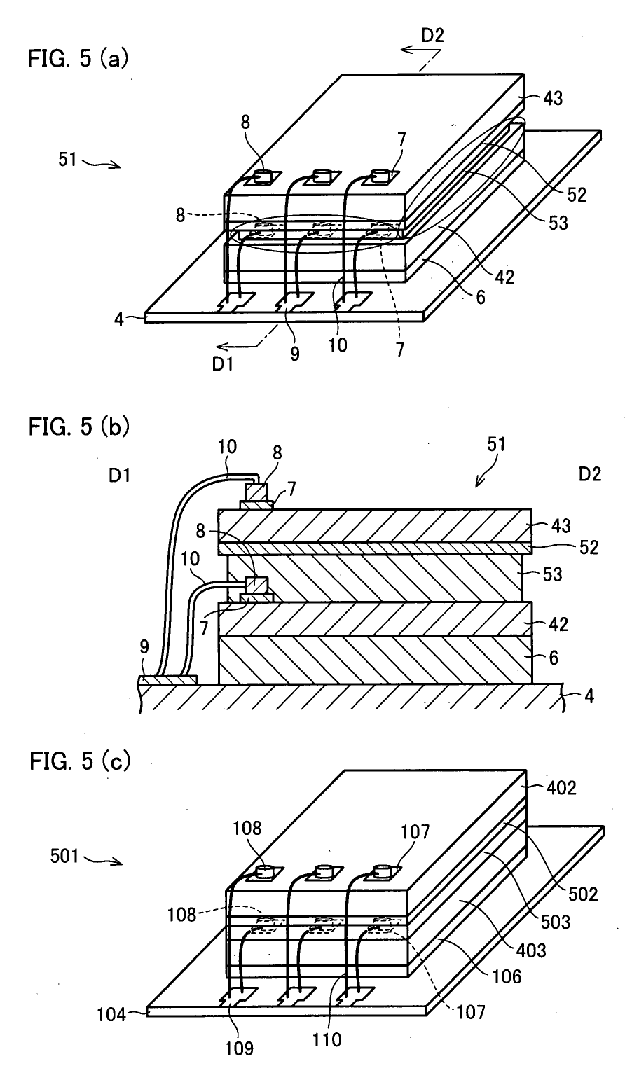

Further, the adhesive layer 52 has a size identical to that of the semiconductor chips 42 and 43. The adhesive layer 53 has a size smaller than that of the adhesive layer 52, and is not in contact with an outer edge portion of the semiconductor chip 42 (see FIGS. 5(a) and 5(b)).

With this, even in cases where a plurality of semiconductor chips are laminated, it is possible to prevent stress from being concentrated on the outer edge portion of the semiconductor chip 42, so that the semiconductor chip 42 becomes unlikely to be physically damaged. As a result, the reliability (durability) of the semiconductor device 51 can be enhanced.

The electrode terminal 7 provided on the main surface of the semiconductor chip 42, the bump 8 connected to the electrode terminal 7, and part of the wire 10 connected to the bump 8 are covered with the adhesive layer 53.

Further, the adhesive layer 52 is provided between the wire 10 and the semiconductor chip 43, so that the wire 10 and the semiconductor chip 43 make no contact with each other.

With this, the semiconductor chips 42 and 43 are securely insulated from each other.

On the other hand, according to a conventional semiconductor device 501 shown in FIG. 5(c), an adhesive layer for bonding two semiconductor chips to each other is constituted by two layers. However, the two layers have the same size, and have a size identical to that of the two semiconductor chips (semiconductor chips 42 and 43).

That is, the adhesive layer 503 is in contact with the outer edge portion of the semiconductor chip 402, and the adhesive layer 502 is in contact with an outer edge portion of the semiconductor chip 403.

As described above, a semiconductor chip is damaged rapidly due to a contact between (i) an outer edge portion of the semiconductor chip which outer edge portion has a large number of minute physical defects and (ii) an adhesive layer; therefore, the electrical function of the semiconductor chip is easily impaired. For this reason, the semiconductor device 501 is inferior to the semiconductor device 51 in terms of reliability (durability).

### REFERENCE EXAMPLE 3

A semiconductor device 61 of the present reference example is a modified example of the semiconductor device 51 shown in Reference Example 2, and is structured such that an adhesive layer for boding two semiconductor chip of the same size to each other is constituted by two layers of the same size.

As described above, in the semiconductor device 61, the semiconductor chips 42 and 43 are bonded to each other by two layers, namely an adhesive layer 62 and an adhesive layer 53.

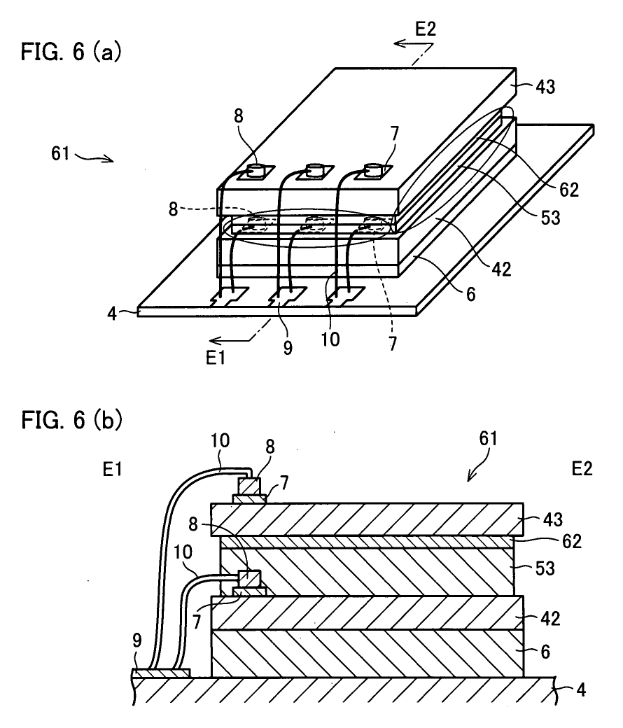

Further, the adhesive layer 62 has a size identical to that of the adhesive layer 53. For this reason, the adhesive layer 62 makes no contact with an outer edge portion of the semiconductor chip 42, and the adhesive layer 53 makes no contact with an outer edge portion of the semiconductor chip 43 (see FIGS. 6(a) and 6(b)).

With this, even in cases where a plurality of semiconductor chips are laminated, it is possible to prevent stress from being concentrated on the outer edge portion of the semiconductor chip 42, so that the semiconductor chip 42 becomes unlikely to be physically damaged. As a result, the reliability (durability) of the semiconductor device 61 can be enhanced.

Furthermore, it is possible to similarly prevent stress from being concentrated on the semiconductor chip 43, so that the semiconductor chip 43 becomes unlikely to be physically damaged. As a result, the reliability (durability) of the semiconductor device 61 can be further enhanced.

On the other hand, according to a conventional semiconductor device 501 shown in FIG. 5(c), an adhesive layer for bonding two semiconductor chips to each other is constituted by two layers. However, the two layers have the same size, and have a size identical to that of the two semiconductor chips (semiconductor chips 42 and 43).

That is, the adhesive layer 503 is in contact with the outer edge portion of the semiconductor chip 402.

As described above, a semiconductor chip is damaged rapidly due to a contact between (i) an outer edge portion of the semiconductor chip which outer edge portion has a large number of minute physical defects and (ii) an adhesive layer; therefore, the electrical function of the semiconductor chip is easily impaired. For this reason, the semiconductor device 501 is inferior to the semiconductor device 61 in terms of reliability (durability).

### REFERENCE EXAMPLE 4

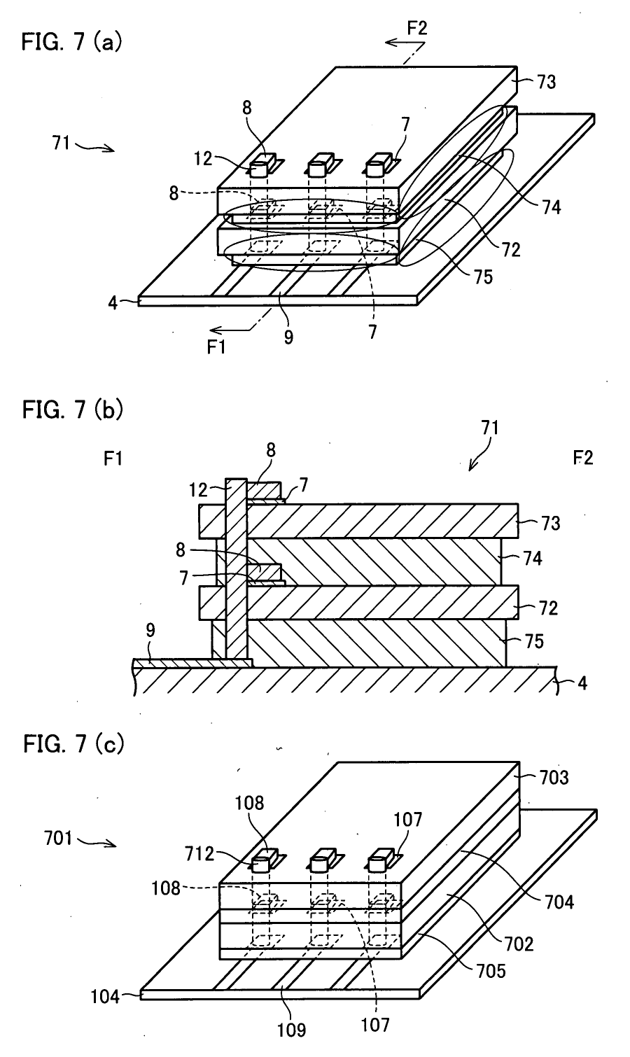

A semiconductor device 71 of the present reference example has a structure, described in Reference Examples 1 to 3, in which semiconductor chips of the same size are laminated, and has a structure in which two semiconductor chips and a substrate are electrically connected by using metal posts passing through the two semiconductor chips. The semiconductor device 71 is described below with reference to FIGS. 7(a) and 7(b).

The connection structure using the metal posts eliminates the use of wire bonding, and is suitable for (i) connecting a circuit pattern formed on a substrate to a circuit pattern formed on a first semiconductor chip and (ii) connecting the circuit pattern formed on the first semiconductor chip to a circuit pattern formed on a second semiconductor chip.

Therefore, even in the protruding laminated structure shown in FIGS. 1(a) through 1(c), the wire bonding can be replaced by a connection structure using metal posts.

The semiconductor device 71 of the present reference example includes an insulating substrate 4, an adhesive layer 75 adhering to that surface of the substrate 4 which is provided with a wiring pattern 9, a semiconductor chip 72 whose back surface adheres to the adhesive layer 75, an adhesive layer 74 adhering to a main surface of the semiconductor chip 72, and a semiconductor chip 73 whose back surface adheres to the adhesive layer 74.

Further, on the main surface of the semiconductor chip 72, a plurality of electrode terminals 7 are provided. Similarly, on a main surface of the semiconductor chip 73, a plurality of electrode terminals 7 are provided. Connected respectively to the electrode terminals 7 are bumps 8.

Furthermore, a bump 8 formed on the main surface of the semiconductor chip 72 and a bump 8 formed on the main surface of the semiconductor chip 73 are connected to each other by a metal post 76 passing through the semiconductor chip 72, the semiconductor chip 73, the adhesive layer 74, and the adhesive layer 75. The metal post 76 is connected to the wiring pattern 9 formed on the substrate 4.

Each of the semiconductor chips 72 and 73 is provided with through-holes through which the metal posts 76 pass. Further, also in cases where the adhesive layers 74 and 75 are a sheet-like adhesive, the adhesive layers 74 and 75 are similarly provided with through-holes.

Here, the adhesive layer 74 adheres to the main surface of the semiconductor chip 72 so as to be short of an outer edge of the main surface of the semiconductor chip 72. That is, the adhesive layer 74 is not in contact with the outer edge portion of the main surface of the semiconductor chip 72.

Similarly, the adhesive layer 75 is not in contact with an outer edge of the back surface of the semiconductor chip 72 (see FIGS. 7(a) and 7(b)).

With this, even in cases where a plurality of semiconductor chips are laminated, it is possible to prevent stress from being concentrated on the outer edge portion of the semiconductor chip 72, so that the semiconductor chip 72 becomes unlikely to be physically damaged. As a result, the reliability (durability) of the semiconductor device 71 can be enhanced.

Furthermore, the adhesive layer 71 is not in contact with an outer edge portion of the semiconductor chip 73 (see FIGS. 7(a) and 7(b)).

With this, the semiconductor chip 73 similarly becomes unlikely to be physically damaged due to stress concentration, so that the reliability (durability) of the semiconductor device 71 can be further enhanced.

On the other hand, in a conventional semiconductor device 701 shown in FIG. 7(c), an adhesive layer 704 is in contact with an outer edge of a main surface of a semiconductor chip 702, and an adhesive layer 705 is in contact with an outer edge of a back surface of the semiconductor chip 702.

Further, the adhesive layer 704 is in contact with an outer edge of a back surface of a semiconductor chip 703.

As described above, a semiconductor chip is damaged rapidly due to a contact between (i) an outer edge portion of the semiconductor chip which outer edge portion has a large number of minute physical defects and (ii) an adhesive layer; therefore, the electrical function of the semiconductor chip is easily impaired. For this reason, the semiconductor device 701 is inferior to the semiconductor device 71 in terms of reliability (durability).

### REFERENCE EXAMPLE 5

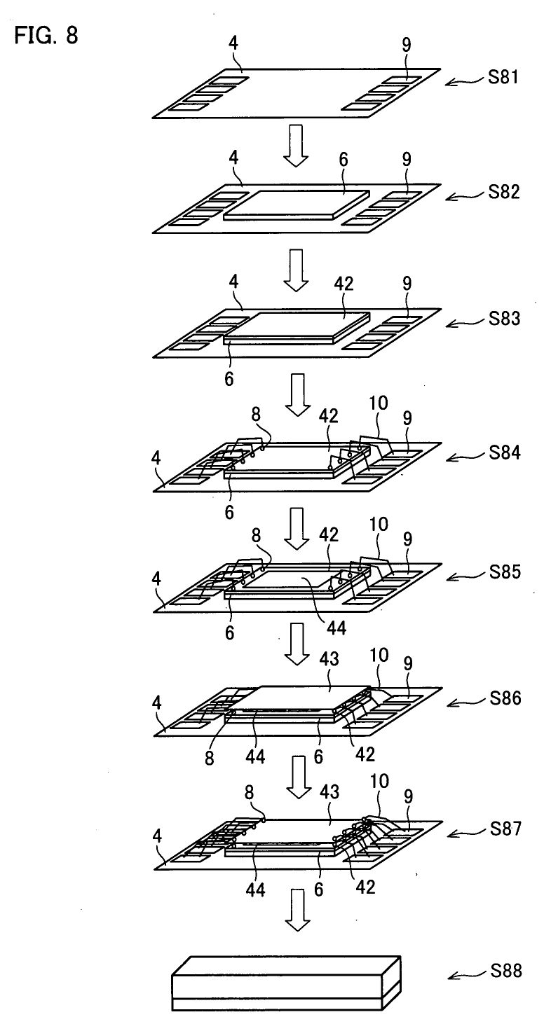

Referring to FIG. 8, the present reference example explains an example of a method for manufacturing a semiconductor device, described in Reference Examples 1 to 3, which is structured such that (i) two semiconductor chips of the same size are laminated above a substrate and (ii) the two semiconductor chips overlaps with each other when the laminated structure in which the two semiconductor chips are laminated is observed directly from above.

In a first step, an insulating substrate 4 provided with a wiring patter 9 is prepared (S81).

In a second step, a first adhesive layer 6 is formed on that surface of the substrate 4 on which is provided with the wiring pattern 9 (S82).

Here, the adhesive layer is formed by using a sheet-like adhesive which has a uniform thickness and which makes it easy to determine a position of adhesion. However, the adhesive layer only needs to be made of an adhesive that can be prevented from adhering to an outer edge portion of a semiconductor chip.

In a third step, a first semiconductor chip 42 is disposed (S83).

Here, the semiconductor chip 42 has a main surface provided with electrode terminals 7, has a back surface ground in advance, and is obtained by dicing.

Further, in FIGS. 4 through 6, an outer edge portion of the back surface of the first semiconductor chip 42 is in contact with the adhesive layer 6. However, in Step 82, the adhesive layer 6 may have a smaller area so as not to make contact with the outer edge of the semiconductor chip 42.

In a fourth step, each of the electrode terminals 7 formed on the first semiconductor chip 42 and the wiring pattern 9 formed on the substrate 4 are electrically connected to each other by wire bonding (S84).

Here, after a bump 8 that has been formed on each of the electrode terminals 7 may be connected to the wiring patter 9 by a wire 10. Alternatively, a bump 8 that has been formed in an end portion of a wire 10 may be connected to the electrode terminal 7.

In a fifth step, a second adhesive layer 44 is formed on the main surface of the first semiconductor chip 42 (S85).

Here, the size of the second adhesive layer 44 and the position of adhesion of the second adhesive layer 44 need to be accurately determined so that the second adhesive layer 44 does not make contact with an outer edge of the main surface of the first semiconductor chip 42.

Further, in some cases, the second adhesive layer 44 is constituted by two layers, and the two layers constituting the second adhesive layer 44 may or may not be of the same size.

In a sixth step, a second semiconductor chip 43 is laminated on the second adhesive layer 44 formed on the main surface of the first semiconductor chip 42 (S86).

On this occasion, in cases where the laminated structure is observed directly from above, the second semiconductor chip 43 is laminated so that an outer edge portion of the second semiconductor chip 43 overlaps with the outer edge portion of the first semiconductor chip 42.

Further, in cases where the laminated structure is observed directly from above, it is only necessary that part of the outer edge of the first semiconductor chip 42 overlaps with part of the outer edge of the second semiconductor chip 43.

That is, it is not always necessary to laminate two semiconductor chips having the same size.

Furthermore, the second semiconductor chip 43 has a main surface provided with electrode terminals 7, has a back surface ground in advance, and is obtained by dicing.

In a seventh step, each of the electrode terminals 7 formed on the second semiconductor chip 43 and the wiring pattern 9 formed on the substrate 4 are electrically connected to each other by wire bonding (S87).

Here, the electrical connection is made by wire boding in the same manner as in S84.

In an eighth step, the laminated structure which has been formed on the substrate and in which the two semiconductor chips are laminated is packaged by plastic molding (S88).

Here, examples of a method for packaging the laminated structure by plastic molding include, but is not limited to, a transfer molding method, a potting method, and the like. As the method for packaging the laminated structure by plastic molding, a conventional well-known method can be suitably used.

The present embodiment takes plastic molding as an example. However, a highly moisture-resistant airtight sealant made of an inorganic substance such as ceramic, glass, or metal may be used.

The aforementioned steps make it possible to manufacture a semiconductor device, according to the present invention, described in Reference Examples 1 to 3.

Note that a semiconductor device described in Reference Example 4 can be manufactured by changing the aforementioned steps in the following manner.

(1) Before the first and second semiconductor chips are disposed, holes through which metal posts are allowed to pass are formed in advance in desired positions in the first and second semiconductor chips.

(2) The first and second adhesive layers are formed so as to be provided with holes through which the metal posts are allowed to pass. Alternatively, after the adhesive layers have been formed and before the semiconductor chips are bonded, the adhesive layers are provided with holes through which the metal posts are allowed to pass.

(3) S84 and S87 are omitted. Instead, after the second semiconductor chip has been laminated, the metal posts are disposed in the through-holes formed in (1) and (2). With this, the substrate, the first semiconductor chip, and the second semiconductor chip are electrically connected.

The above description explains an example of the method for manufacturing a semiconductor device of Reference Examples of 1 to 4. However, a person skilled in the art can easily imagine that a conventional well-known semiconductor device manufacturing step can be used for manufacturing a semiconductor device of the present invention and that the aforementioned steps can be appropriately altered as needed.

The present invention is not limited to the description of the embodiments above, but may be altered by a person skilled in the art within the scope of the claims. An embodiment based on a proper combination of technical means disclosed in different embodiments is encompassed in the technical scope of the present invention.

Further, the semiconductor device of the present invention may be arranged such that the adhesive layer further adheres to the second semiconductor chip.

Further, the semiconductor device of the present invention is preferably arranged such that the adhesive layer adheres to the second semiconductor chip so as to be short of an outer edge of the second semiconductor chip.

The foregoing arrangement makes it possible to also prevent stress from being concentrated on an outer edge portion of the second semiconductor chip laminated above the first semiconductor chip.

This brings about the same effects as those described above.

Further, the semiconductor device of the present invention may be arranged such that the back surface of the second semiconductor chip adheres to the main surface of the first semiconductor chip via the adhesive layer.

That is, a laminated structure in which a plurality of semiconductor chips are laminated includes a structure in which two semiconductor chips are laminated so that their respective main surfaces face in the same direction.

With this, even in cases where the semiconductor device is arranged as described above, the same effects as those described above are obtained.

Further, the semiconductor device of the present invention may be arranged such that the main surface of the second semiconductor chip adheres to the main surface of the first semiconductor chip via the adhesive layer.

That is, a laminated structure in which a plurality of semiconductor chips are laminated includes a structure in which two semiconductor chips are laminated so that their respective main surfaces face each other.

With this, even in cases where the semiconductor device is arranged as described above, the same effects as those described above are obtained.

Further, the semiconductor device of the present invention may be arranged such that the main surface of the second semiconductor chip adheres to the back surface of the first semiconductor chip via the adhesive layer.

That is, a laminated structure in which a plurality of semiconductor chips are laminated includes a structure in which two semiconductor chips are laminated so that their respective main surfaces face in the same direction. However, the respective main surfaces of the two semiconductor chips face in a direction opposite to the direction in which they face in the laminated structure in which the back surface of the semiconductor chip adheres to the main surface of the first semiconductor chip.

With this, even in cases where the semiconductor device is arranged as described above, the same effects as those described above are obtained.

Further, the semiconductor device of the present invention may be arranged so as to further include: a substrate provided with a wiring pattern; and a substrate adhesion layer via which the main surface or back surface of the first semiconductor chip adheres to the substrate, wherein the electrode terminals are connected, via a plurality of electrical conductors, to the wiring pattern formed on the substrate, respectively.

The foregoing arrangement is either of the following arrangements: (1) that surface of the substrate which is provided with the wiring pattern and the respective main surfaces of the two semiconductor chips face in the same direction; and (2) that surface of the substrate which is provided with the wiring pattern faces the respective main surfaces of the two semiconductor chips. Furthermore, the foregoing arrangement may be an arrangement in which the two semiconductor chips whose respective main surfaces face each other are laminated above that surface of the substrate which is provided with the wiring pattern.

In any one of the foregoing arrangements, the same effects as those described above are obtained.

Further, the semiconductor device of the present invention is preferably arranged such that the substrate adhesion layer adheres to the first semiconductor chip so as to be short of the outer edge of the first semiconductor chip.

The foregoing arrangement prevents stress from being concentrated on an outer edge of that surface of the first semiconductor chip which faces the substrate, the first semiconductor chip being laminated above the substrate.

With this, in addition to the aforementioned effects, the reliability (durability) of the semiconductor device can be further enhanced.

Further, the semiconductor device of the present invention is preferably arranged such that the adhesive layer is a sheet adhesive.

The foregoing arrangement makes it easy to form an adhesive layer having a uniform thickness and a desired size. Note that the same effects are obtained when the substrate adhesion layer is a sheet-like adhesive.

With this, a plurality of semiconductor chips can be laminated in parallel with the substrate, and an adhesive layer can be easily formed so as to be situated in a desired position.

The embodiments and concrete examples of implementation discussed in the foregoing detailed explanation serve solely to illustrate the technical details of the present invention, which should not be narrowly interpreted within the limits of such embodiments and concrete examples, but rather may be applied in many variations within the spirit of the present invention, provided such variations do not exceed the scope of the patent claims set forth below.

What is claimed is:

1. A semiconductor device, comprising:
a first semiconductor chip having a main surface provided with electrode terminals and a back surface that is on an opposite side of the main surface;
a second semiconductor chip having a main surface provided with electrode terminals and a back surface that is on an opposite side of the main surface;
an adhesive layer, sandwiched between the first and second semiconductor chips, which adheres to the first semiconductor chip,
the first and second semiconductor chips being laminated so that part of the second semiconductor chip protrudes outwards from an outer edge of the first semiconductor chip,
in an outer edge portion of the first semiconductor chip from whose outer edge the part of the second semiconductor chip protrudes outwards, the adhesive layer adhering to the first semiconductor chip so as to be short of the outer edge of the first semiconductor chip.

2. The semiconductor device as set forth in claim 1, wherein the adhesive layer further adheres to the second semiconductor chip.

3. The semiconductor device as set forth in claim 1, wherein the adhesive layer further adheres to the second semiconductor chip so as to be short of an outer edge of the second semiconductor chip.

4. The semiconductor device as set forth in claim 1, wherein the back surface of the second semiconductor chip adheres to the main surface of the first semiconductor chip via the adhesive layer.

5. The semiconductor device as set forth in claim 4, further comprising:
a substrate provided with a wiring pattern; and
a substrate adhesion layer via which the main surface or back surface of the first semiconductor chip adheres to the substrate, wherein
the electrode terminals are connected, via a plurality of electrical conductors, to the wiring pattern formed on the substrate, respectively.

6. The semiconductor device as set forth in claim 5, wherein the substrate adhesion layer adheres to the first semiconductor chip so as to be short of the outer edge of the first semiconductor chip.

7. The semiconductor device as set forth in claim 1, wherein the main surface of the second semiconductor chip adheres to the main surface of the first semiconductor chip via the adhesive layer.

8. The semiconductor device as set forth in claim 7, further comprising:
a substrate provided with a wiring pattern; and
a substrate adhesion layer via which the main surface or back surface of the first semiconductor chip adheres to the substrate, wherein
the electrode terminals are connected, via a plurality of electrical conductors, to the wiring pattern formed on the substrate, respectively.

9. The semiconductor device as set forth in claim 8, wherein the substrate adhesion layer adheres to the first semiconductor chip so as to be short of the outer edge of the first semiconductor chip.

10. The semiconductor device as set forth in claim 1, wherein the main surface of the second semiconductor chip adheres to the back surface of the first semiconductor chip via the adhesive layer.

11. The semiconductor device as set forth in claim 10, further comprising:
a substrate provided with a wiring pattern; and
a substrate adhesion layer via which the main surface or back surface of the first semiconductor chip adheres to the substrate, wherein
the electrode terminals are connected, via a plurality of electrical conductors, to the wiring pattern formed on the substrate, respectively.

12. The semiconductor device as set forth in claim 11, wherein the substrate adhesion layer adheres to the first semiconductor chip so as to be short of the outer edge of the first semiconductor chip.

13. The semiconductor device as set forth in claim 1, wherein the adhesive layer is a sheet adhesive.
